(19) United States
(12) Patent Application Publication
(10) Pub. No.: US 2013/0270109 A1
(43) Pub. Date: Oct. 17, 2013

(54) OXIDE FOR SEMICONDUCTOR LAYER OF THIN-FILM TRANSISTOR, SPUTTERING TARGET, AND THIN-FILM TRANSISTOR

(71) Applicants: Shinya Morita, Kobe-shi (JP); Aya Miki, Kobe-shi (JP); Satoshi Yasuno, Kobe-shi (JP); Toshihiro Kugimiya, Kobe-shi (JP); Tomoya Kishi, Kobe-shi (JP)

(72) Inventors: Shinya Morita, Kobe-shi (JP); Aya Miki, Kobe-shi (JP); Satoshi Yasuno, Kobe-shi (JP); Toshihiro Kugimiya, Kobe-shi (JP); Tomoya Kishi, Kobe-shi (JP)

(73) Assignee: Kabushiki Kaisha Kobe Seiko Sho (Kobe Steel, Ltd.), Kobe-shi (JP)

(21) Appl. No.: 13/994,467

(22) PCT Filed: Dec. 28, 2011
(86) PCT No.: PCT/JP2011/080483

§ 371 Date: Jun. 14, 2013

(30) Foreign Application Priority Data
Dec. 28, 2010 (JP) 2010-292929

(51) Int. Cl. H01L 27/01

(52) U.S. Cl. CPC H01L 27/016
USPC 204/298.13; 423/326; 423/598; 423/600; 423/263; 423/594.8; 423/594.14; 252/519.12; 252/519.13

(57) ABSTRACT

The oxides for semiconductor layers of thin-film transistors according to the present invention include: In; Zn; and at least one element (X group element) selected from the group consisting of Al, Si, Ta, Ti, La, Mg and Nb. The present invention makes it possible to provide oxides for semiconductor layers of thin-film transistors, in which connection thin-film transistors with In—Zn—O oxide semiconductors not containing Ga have favorable switching characteristics and high stress resistance, and in particular, show a small variation of the threshold voltage before and after positive bias stress tests, thereby having high stability.

### TECHNICAL FIELD

The present invention relates to an oxide for semiconductor layers of thin-film transistors to be used in display devices such as liquid crystal displays and organic EL displays; a sputtering target for forming the oxide; and a thin-film transistor with the oxide.

### BACKGROUND ART

As compared with widely used amorphous silicon (a-Si), amorphous (non-crystalline) oxide semiconductors have high carrier mobility (also called as field-effect mobility, which may hereinafter be referred to simply as “mobility”), high optical band gaps, and film formability at low temperatures, and therefore, have highly been expected to be applied for next generation displays, which are required to have large sizes, high resolution, and high-speed drives; resin substrates having low heat resistance; and others.

In the oxide semiconductors, amorphous oxide semiconductors consisting of indium, gallium, zinc and oxygen (In—Ga—Zn—O, which may hereinafter be referred to as “IGZO”) have preferably been used, in particular, because of their having extremely high carrier mobility. For example, non-patent literature documents 1 and 2 disclose thin-film transistors (TFTs) in which a thin-film of an oxide semiconductor having an In:Ga:Zn ratio equal to 1.1:1.1:0.9 (atomic % ratio) was used as a semiconductor layer (active layer). In addition, patent document 1 discloses an amorphous oxide containing In, Zn, Sn, Ga and other elements, as well as Mo, in which the atomic composition ratio of Mo, relative to the number of all the metal atoms in the amorphous oxide, is from 0.1 to 5 atomic %. Examples of patent document 1 disclose TFTs each using an active layer formed by the addition of Mo to IGZO.

When an oxide semiconductor is used as a semiconductor layer of a thin-film transistor, the oxide semiconductor is required to have a high carrier concentration (mobility) and excellent TFT switching characteristics (transistor characteristics, TFT characteristics). More specifically, the oxide semiconductor is required to have, for example, (1) a high on-state current (i.e., the maximum drain current when a positive voltage is applied to both a gate electrode and a drain electrode); (2) a low off-state current (i.e., a drain current when a negative voltage is applied to the gate electrode and a positive voltage is applied to the drain voltage, respectively); (3) a low S value (subthreshold swing, i.e., a gate voltage needed to increase the drain current by one digit); (4) a stable threshold value (i.e., a voltage at which the drain current starts to flow when a positive voltage is applied to the drain electrode and either a positive voltage or a negative voltage is applied to the gate voltage, which voltage may also be called as a threshold voltage) showing no change with time (which means that the threshold voltage is uniform in the substrate surface); and (5) a high mobility (carrier mobility, filed-effect mobility).

Furthermore, TFTs using IGZO or other oxide semiconductor layers are required to have excellent resistance to stress such as voltage application and light irradiation (stress resistance). It has been pointed out that, for example, when a positive voltage or a negative voltage is continuously applied to the gate electrode or when light in a blue emitting band in which light absorption starts is continuously irradiated, the threshold voltage highly varies (shifts), thereby causing a variation in the switching characteristics of TFTs. In particular, a shift of the threshold voltage leads to a lowering in the reliability of display devices with TFTs, such as liquid crystal displays or organic EL displays. Therefore, an improvement in the stress resistance (a small variation before and after stress tests) has eagerly been desired.

For example, when TFTs are used for organic EL display application, the TFTs are required to have high stress resistance to positive bias in which a positive voltage is applied to the gate electrode for a long time, because light-emitting elements are driven by current control. The application of positive bias to the gate electrode for a long time causes the accumulation of electrons on the boundary between the gate insulator layer and the semiconductor layer in the TFTs, resulting in a shift of the threshold voltage responsible for a lowering of reliability as described above.

As a method of controlling such a threshold voltage shift caused by stress of positive bias, patent document 2 discloses a technique of layering an insulator layer by forming an oxide-containing boundary stabilizing layer having the same properties as those of the insulator layer on the boundary between the oxide semiconductor liable to cause the occurrence of defects and the gate insulator layer. This method improves stress resistance to positive bias, but requires the formation of an insulator layer from two different materials, which leads to an increase of cost and a lowering of productivity, such as a need to use an additional sputtering target and an additional film formation chamber.

As a method of improving the stability of TFTs by tuning the surrounding process, there has been proposed a method of using an Al₂O₃ film or other films not containing hydrogen for the gate insulator layer. However, this method also requires a need to prepare a new film formation chamber to form an Al₂O₃ film, which leads to an inevitable increase of cost.

On the other hand, Ga in the metals (In, Ga and Zn) forming IGZO has excellent band gap increase action and makes a strong bond to oxygen, but has mobility lowering action. Therefore, In—Zn—O oxide semiconductors (IZO) not containing Ga provides high mobility as compared with IGZO, but has a problem that it is liable to cause the occurrence of oxygen defects, thereby easily making the TFT characteristics unstable.

### PRIOR ART DOCUMENTS

### Patent Documents

Patent Document 1: Japanese Patent Laid-open Publication (Kokai) No. 2009-164393
Patent Document 2: Japanese Patent Laid-open Publication (Kokai) No. 2010-016347

### Non-Patent Literature Documents

Non-patent Literature Document 1: Solid State Physics, Vol. 44, p. 621 (2009)
Non-patent Literature Document 2: Nature, Vol. 432, p. 488 (2004)

### SUMMARY OF THE INVENTION

### Problems to be Solved by the Invention

The present invention has been completed under the circumstances described above, and an object of the present invention is to provide an oxide for semiconductor layers of thin-film transistors, in which connection thin-film transistors with In—Zn—O oxide semiconductors not containing Ga have favorable switching characteristics and high stress resistance, and in particular, show a small variation of the threshold voltage before and after positive bias stress tests, thereby having high stability, and the oxide is particularly suitable for application to organic EL display devices; a sputtering target to be used for the formation of an oxide for semiconductor layers as described above; a thin-film transistor using an oxide for semiconductor layers as described above; and a display device.

### Means for Solving the Problems

The oxide for semiconductor layers of thin-film transistors according to the present invention, which was able to solve the problems described above, comprises: In; Zn; and at least one element (X group element) selected from the group consisting of Al, Si, Ta, Ti, La, Mg and Nb.

In a preferred embodiment of the present invention, the X amount defined by the formula: 100×[X]/([In]+[Zn]+[X]) is from 0.1 to 5 atomic % where [In], [Zn] and [X] express the content (atomic %) of the In, the content (atomic %) of the Zn, and the content (atomic %) of the X group element, respectively, all contained in the oxide for semiconductor layers.

In a preferred embodiment of the present invention, the In amount defined by the formula: 100×[In]/([In]+[Zn]+[X]) is 15 atomic % or larger where [In], [Zn] and [X] express the content (atomic %) of the In, the content (atomic %) of the Zn, and the content (atomic %) of the X group element, respectively, all contained in the oxide for the semiconductor layer.

In a preferred embodiment of the present invention, the X group element is Al, Ti or Mg.

In a preferred embodiment of the present invention, the oxide for semiconductor layers is formed by a sputtering method.

The present invention further includes a thin-film transistor comprising, as a semiconductor layer of the thin-film transistor, any oxide for semiconductor layers as described above.

In a preferred embodiment of the present invention, the semiconductor layer has a density of 6.0 g/cm³ or higher.

The present invention further includes a display device comprising a thin-film transistor as described above.

The present invention further includes an organic EL display device comprising a thin-film transistor as described above.

The sputtering target of the present invention, which was able to solve the problems described above, is a sputtering target for forming any oxide for semiconductor layers as described above, the sputtering target comprising: In; Zn; and at least one element (X group element) selected from the group consisting of Al, Si, Ta, Ti, La, Mg and Nb.

In a preferred embodiment of the present invention, the X amount defined by the formula: 100×[X]/([In]+[Zn]+[X]) is from 0.1 to 5 atomic % where [In], [Zn] and [X] express the content (atomic %) of the In, the content (atomic %) of the Zn, and the content (atomic %) of the X group element, respectively, all contained in the oxide for the semiconductor layer.

In a preferred embodiment of the present invention, the In amount defined by the formula: 100×[In]/([In]+[Zn]+[X]) is 15 atomic % or larger where [In], [Zn] and [X] express the content (atomic %) of the In, the content (atomic %) of the Zn, and the content (atomic %) of the X group element, respectively, all contained in the oxide for the semiconductor layer.

In a preferred embodiment of the present invention, the X group element is Al, Ti or Mg.

### Effects of the Invention

The oxide for semiconductor layers of the present invention made it possible to provide thin-film transistors, which have excellent switching characteristics and high stress resistance, and in particular, which show a small threshold voltage variation after positive bias stress tests, thereby having excellent TFT characteristics and high stress resistance to positive bias. As a result, display devices with high reliability can be obtained by the use of thin-film transistors as described above. The oxide for semiconductor layers of the present invention is particularly suitably used for EL display devices, which are required to have stress resistance to positive bias and current stress resistance.

### BRIEF DESCRIPTION OF DRAWINGS

FIG. 1 is a schematic cross-sectional view for the explanation of a thin-film transistor with a semiconductor layer.

FIG. 2 is a schematic cross-sectional view for the explanation of a structure in which the thin-film transistor of FIG. 1 is provided with an etch stopper layer.

FIG. 3 is a graph showing TFT characteristics observed when IGZO (conventional example) is used in the oxide semiconductor layer.

FIG. 4 is a graph showing TFT characteristics observed when In—Zn—Sn—O (comparative example) is used in the oxide semiconductor layer.

FIGS. 5A(a) to (d) are graphs each showing TFT characteristics observed when In—Zn—X—O where the X group element is Si, Al, Ta or Ti (inventive example) is used in the oxide semiconductor layer. FIG. 5A(e) is a graph showing the TFT characteristics observed when In—Zn—Hf—O (comparative example) is used in the semiconductor layer.

FIGS. 5B(a) to (c) are graphs each showing TFT characteristics observed when In—Zn—X—O where the X group element is La, Mg or Nb (inventive example) is used in the oxide semiconductor layer.

FIG. 6 is a graph showing the influence of the X amount to the filed-effect mobility in the In—Zn—X—O.

FIG. 7 is a graph showing the influence of the In amount to the filed-effect mobility in the In—Zn—X—O.

FIG. 8A is a graph showing the results of positive bias stress tests obtained when In—Zn—X—O (X=Si, Al, Ta or Ti; inventive example) or In—Zn—(Hf or Sn)—O (comparative example) is used in the oxide semiconductor layer.

FIG. 8B is a graph showing the results of the positive bias stress test obtained when In—Zn—X—O (X=La, Mg or Nb; inventive example) is used in the oxide semiconductor layer.

FIG. 9A is a graph showing the influence of the kind of the X group element to a time variation of the threshold voltage in the positive bias stress in the In—Zn—X—O.

FIG. 9B is a partially enlarged view of FIG. 9A.

### MODE FOR CARRYING OUT THE INVENTION

The present inventors have made various studies to improve TFT characteristics and stress resistance (particularly stress resistance after positive bias tests) when an In—Zn—O oxide (IZO) containing In and Zn but not containing Ga is used for active layers (semiconductor layers) of TFTs. As a result, they have found that an intended object can be achieved by the use of In—Zn—X—O containing at least one element (X group element) selected from the group (X group) consisting of Al, Si, Ta, Ti, La, Mg and Nb in IZO for semiconductor layers of TFTs, thereby completing the present invention. As shown in Examples described below, TFTs, each of which has an oxide semiconductor containing an element (X group element) belonging to the X group described above in IZO, have higher mobility than that of IGZO and excellent stress resistance after positive bias tests. In contrast to this, TFTs, each of which has an oxide semiconductor containing an element (e.g., Hf or Sn) other than the X group element described above, have high mobility, but have significantly reduced stress resistance after positive bias tests.

In short, the oxide for semiconductor layers of thin-film transistors (TFTs) according to the present invention comprises: In; Zn; and at least one X group element selected from the X group consisting of Al, Si, Ta, Ti, La, Mg and Nb.

In the present specification, the oxide of the present invention may be expressed by In—Zn—X—O. In the following description, as for all the metals (In, Zn and X group element) contained in the oxide (In—Zn—X—O) of the present invention, the X amount (atomic %) expressed by the formula: 100×[X]/([In]+[Zn]+[X]) may be abbreviated simply as the X amount, when the contents (atomic %) of In, Zn and X group element contained in the oxide are expressed by [In], [Zn] and [X], respectively, in which when the oxide contains one X group element, [X] is a single amount of this X group element, or when the oxide contains two or more X group element, [X] is a total amount of these X group elements. Similarly, the In amount (atomic %) expressed by the formula: 100×[In]/([In]+[Zn]+[X]) may be abbreviated simply as the In amount.

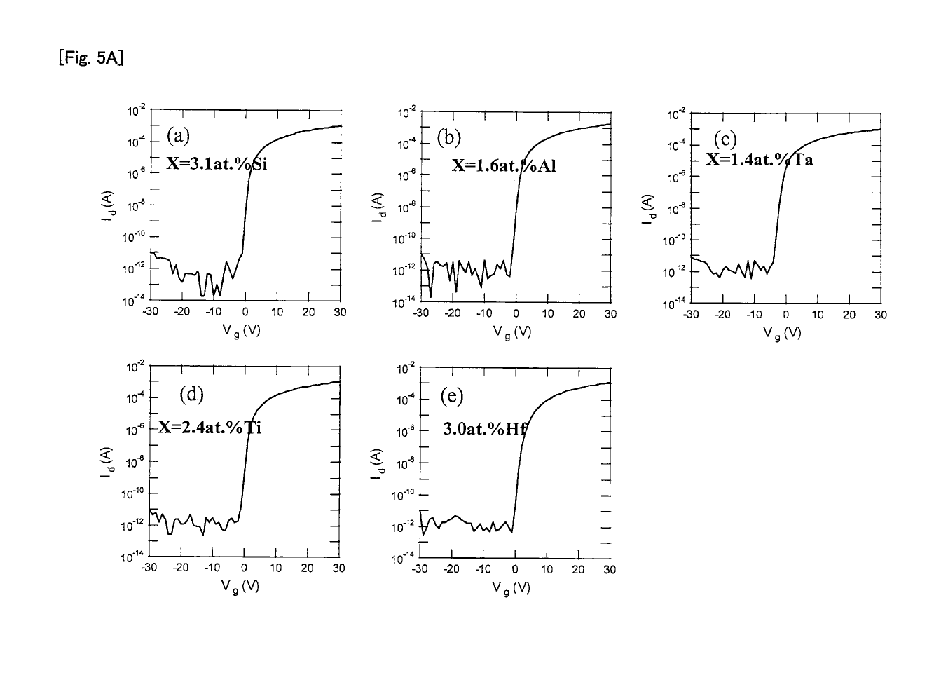

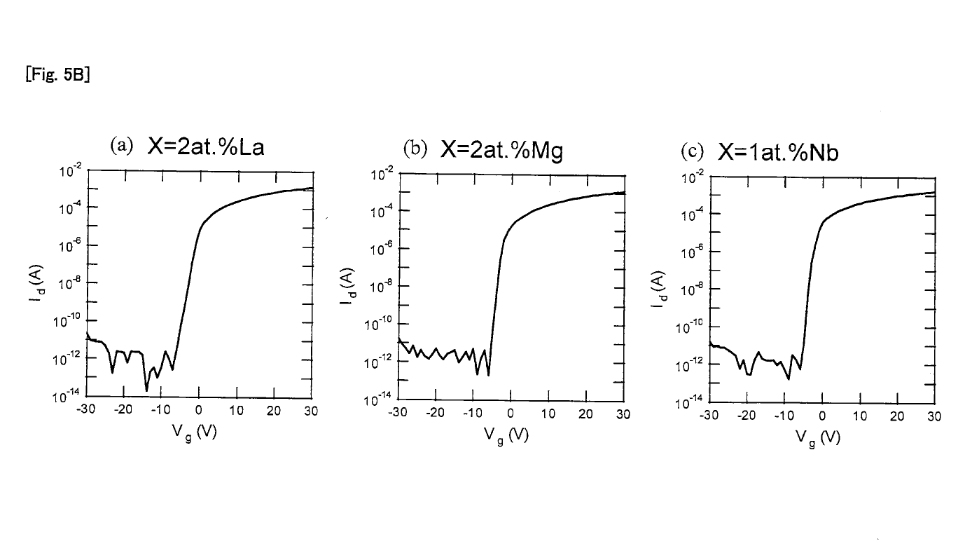

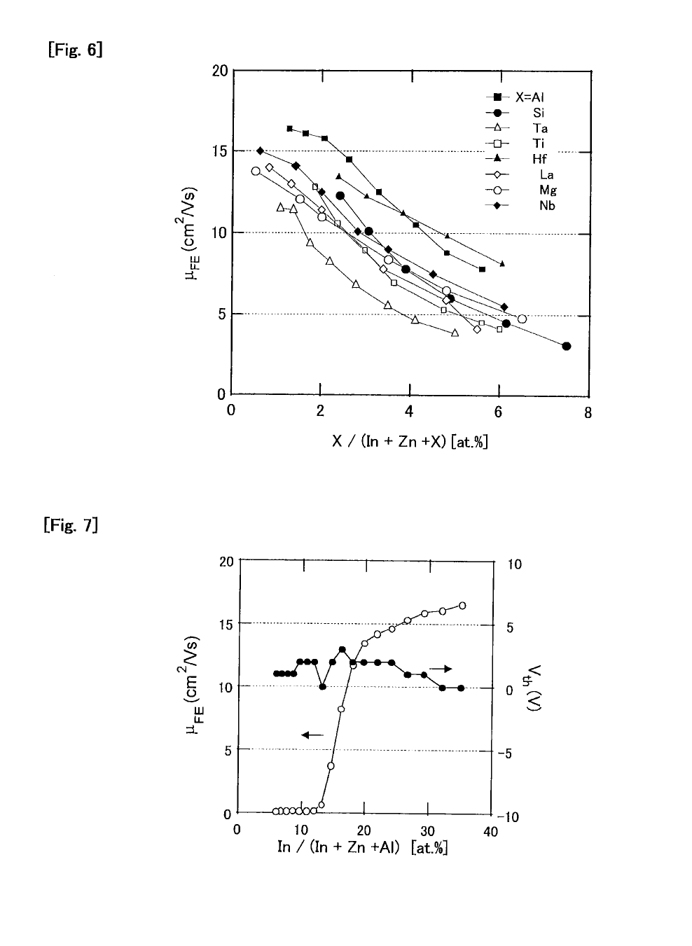

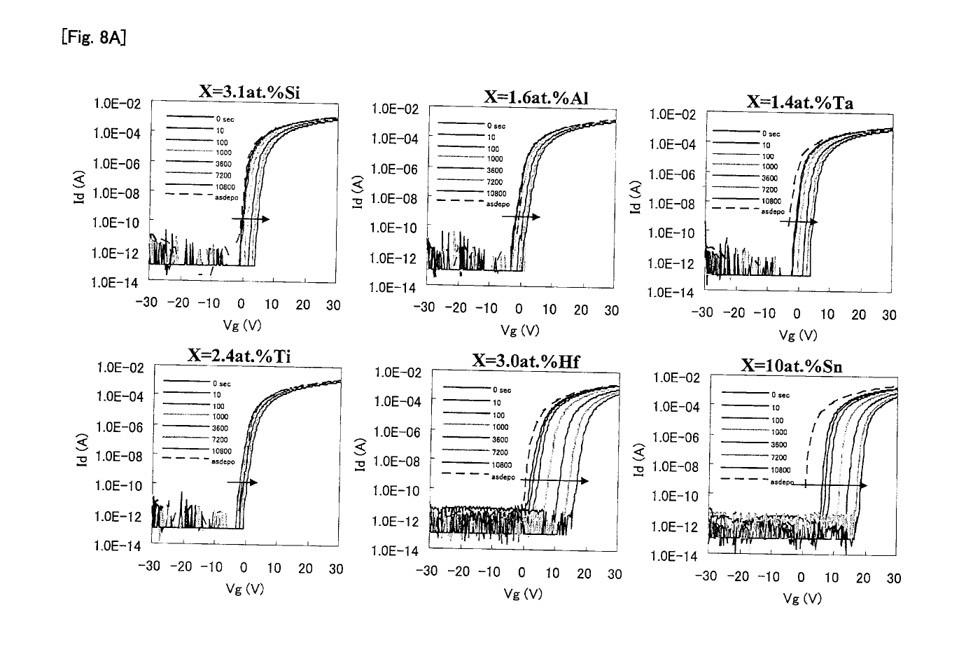

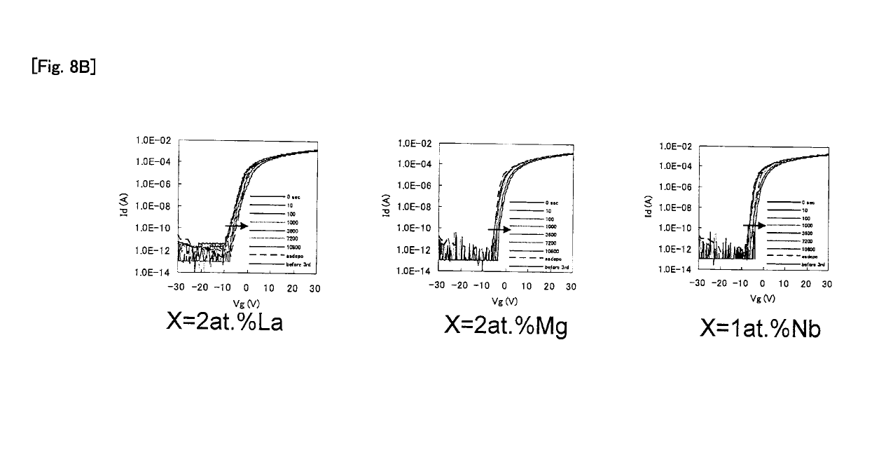

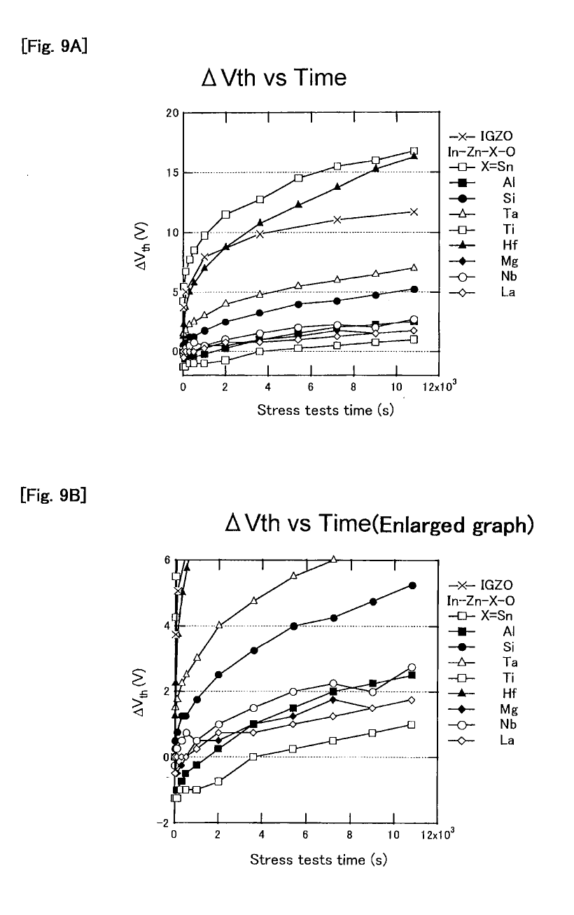

The present invention is characterized in that In—Zn—O contains an X group element as described above in a specific amount range. As shown in Examples described below, the X group element has the action of improving stability to positive bias stress (stress resistance to positive bias) and can significantly reduce threshold voltage variation ΔVth after positive bias tests (see FIGS. 8 and 9) as compared with the case where an element (Sn or Hf) other than the X group element defined in the present invention is added. The content of the X group element is properly controlled in the present invention, and therefore, high mobility can be ensured (see FIG. 6). A large lowering of the drain current value is not observed by the addition of the X group element, so that favorable TFT characteristics can be exhibited (see FIG. 5). It was confirmed by experiments that serious problems such as etching failure in the wet etching are not caused by the addition of the X group element. The X group element can be added alone, or two or more of the X group elements can be used in combination. The X group element may preferably be Al, Ti or Mg, more preferably Al or Ti, and still more preferably Ti.

For the improvement of characteristics by the addition of the X group element described above, although a detailed mechanism is not known, the X group element is assumed to have the effect of suppressing the occurrence of oxygen defects responsible for an excess of electrons in the oxide semiconductor. It seems that oxygen defects are reduced by the addition of the X group element and the oxide has a stable structure, thereby improving resistance to stress such as voltage or light.

The X amount as calculated above may preferably be approximately from 0.1 to 5 atomic %, which may vary with the In amount or other factors. The X amount is determined in view of carrier density and semiconductor stability and may slightly vary with the kind of the X group element. In a precise sense, for example, as shown in FIG. 6 described below, the contents capable of exhibiting the working effect (field-effect mobility in FIG. 6) on the same level may vary with the kind of the X group element, and therefore, the X amount may preferably be controlled in an appropriate and proper manner depending on the kind of the X group element. However, the effect attained by the addition of the X group element has the same tendency, and when the X amount is too small, the effect of suppressing the occurrence of oxygen defects cannot be obtained and a desired effect of positive bias stress resistance cannot be exhibited. On the other hand, when the X amount is too large, the above-described effect is saturated and the carrier density in the semiconductor is lowered, resulting in a reduction of field-effect mobility and on-state current (see FIG. 6 described below). The X amount may more preferably be approximately from 0.5 to 3 atomic %, although it may vary with the kind of the X group.

The following will explain the metals (In and Zn) as the base material components forming the oxide of the present invention.

In the present invention, the In amount as calculated above may preferably be 15 atomic % or larger. The present inventors' experiments revealed that In has the action of improving mobility and shows a tendency that mobility increases with an increase of the In amount even in the oxide (In—Zn—X—O) of the present invention (see FIG. 7). To satisfy the passing criterion (3.8 cm²/Vs or higher) of mobility in Examples described below, the In amount may preferably be set to 15 atomic % or larger, more preferably 20 atomic % or larger. However, when the In amount is too large, TFTs have lowered stability, and therefore, the In amount may preferably be 70 atomic % or smaller, more preferably 50 atomic % or smaller.

As for the metals, In and Zn, as the base material components, the ratio among the respective metals is not particularly limited, so long as it is in the range where oxides containing these metals have amorphous phase and show semiconductor characteristics. In—Zn—O itself is well known even as a transparent conductive film. The ratios of the respective metals (more specifically, the respective molar ratios of InO and ZnO) capable of forming amorphous phase are described in, for example, non-patent literature document 1 recited above.

The results of the present inventors' studies confirmed that when the ratio of In, among the metals contained in In—Zn—O, is too high, the threshold voltage easily shifts on the negative side by a production process or a lapse of time to easily become conductive; and on the other hand, when the ratio of Zn is too high, the processing by wet etching is difficult to easily give an etching residue. Therefore, the atomic ratio of In and Zn may preferably be in a range satisfying that 100×In/(In +Zn)=15 to 70 atomic %.

In the above, the oxide of the present invention was explained.

The oxide described above may preferably be formed by a sputtering method using a sputtering target (which may hereinafter be referred to as the “target”). The oxide can also be formed by a chemical film-formation method such as a coating method, but the use of a supporting method makes it possible to easily form a thin-film having excellent uniformity of composition or film thickness in the film surface.

As a target to be used in the sputtering method, there may preferably be used a sputtering target containing the elements described above and having the same composition as that of a desired oxide, thereby making it possible to form a thin-film causing no deviation of composition and having the same composition as that of the desired oxide. More specifically, as the target, there can be used an oxide target containing: In; Zn; and at least one X group element selected from the X group consisting of Al, Si, Ta, Ti, La, Mg and Nb. Such a sputtering target is also included in the scope of the present invention.

When the contents of In, Zn and X group element contained in the sputtering target are expressed by [In], [Zn] and [X], respectively, the X amount expressed by the formula: 100×[X]/([In]+[Zn]+[X]) may preferably be from 0.1 to 5 atomic %. When the contents (atomic %) of In, Zn and X group element contained in the sputtering target are expressed by [In], [Zn] and [X], respectively, the In amount expressed by the formula: 100×[In]/([In]+[Zn]+[X]) may preferably be 15 atomic % or larger. The X group element described above may preferably be Al, Ti or Mg, more preferably Al or Ti, and more preferably Ti.

Alternatively, film formation may be carried out by a co-sputtering method (co-sputter method), in which two targets with different compositions are simultaneously discharged, and consequently, an oxide semiconductor film with a different content of the X-element can be formed in the surface of the same substrate. For example, a target of indium oxide and zinc oxide, and a target containing the X group element, are prepared, with which an oxide of In—Zn—X—O can be formed by a co-sputtering method. As the target containing the X group element described above, there can be used pure metal targets containing only the X group element, alloy targets containing the X group element, and oxide targets containing the X group element.

The targets described above can be produced by, for example, a powder sintering method.

The sputtering using a target as described above may preferably be carried out under the conditions that substrate temperature is set to room temperature and oxygen addition amount is appropriately controlled. The oxygen addition amount may appropriately be controlled according to the configuration of a sputtering system and the composition of the target. The oxygen addition amount may preferably be controlled by the addition of oxygen so that the carrier concentration of a semiconductor becomes approximately from 10¹⁵ to 10¹⁶ cm⁻³. The oxygen addition amount in the Examples described below was set to satisfy O₂/(Ar+O₂)=2% by the addition flow ratio.

When an oxide as described above is used as the semiconductor layer of a TFT, the oxide semiconductor layer may preferably have a density of 6.0 g/cm³ or higher (described below). To form a film of such an oxide, the sputtering conditions may preferably be controlled in a proper manner, such as gas pressure, input power, and substrate temperature during the sputtering film formation. The density of the oxide is influenced by the conditions of heat treatment after the film formation, and therefore, the conditions of heat treatment after the film formation may preferably be controlled in a proper manner. Such heat treatment can also be controlled, for example, in the heat history during the production process of TFTs. For example, the pre-annealing treatment (heat treatment carried out just after the patterning subsequent to the wet etching of the oxide semiconductor layer) makes an improvement of film density. For example, it is assumed that when the gas pressure is lowered during the film formation, sputtered atoms can be prevented from scattering one another, thereby making it possible to form a dense (high-density) film. Thus, the total gas pressure during the film formation may preferably be as low as possible, and it is recommended to be controlled in a range of approximately from 1 to 5 mTorr. The input power may preferably be as low as possible, and it is recommended to be controlled to approximately 2.0 W/cm² or higher. The substrate temperature during the film formation is recommended to be controlled in a range of approximately from room temperature to 200° C. As the conditions of heat treatment after the film formation, heat treatment is recommended to be carried out, for example, under an air atmosphere approximately at 250° C. to 400° C. for 10 minutes to 3 hours.

The oxide film formed in a manner as described above may preferably have a thickness of from 30 nm to 200 nm, more preferably from 30 nm to 80 nm.

The present invention further includes TFTs each containing an oxide as described above, as a semiconductor layer of each TFT. The TFTs may respectively have at least a gate electrode, a gate insulator layer, a semiconductor layer made of an oxide as described above, a source electrode, and a drain electrode on a substrate. The configuration thereof is not particularly limited, so long as it is usually used.

An oxide semiconductor layer as described above may preferably have a density of 6.0 g/cm³ or higher. An increase in the density of the oxide semiconductor layer causes a reduction of defects in the film to improve film quality, and therefore, the field-effect mobility of each TFT device is highly increased, thereby increasing electric conductivity and improving stability. The oxide semiconductor layer may preferably have a density as higher as possible, more preferably 6.2 g/cm³ or higher, and still more preferably 6.4 g/cm³ or higher. The density of the oxide semiconductor layer is measured by a method described below in Examples.

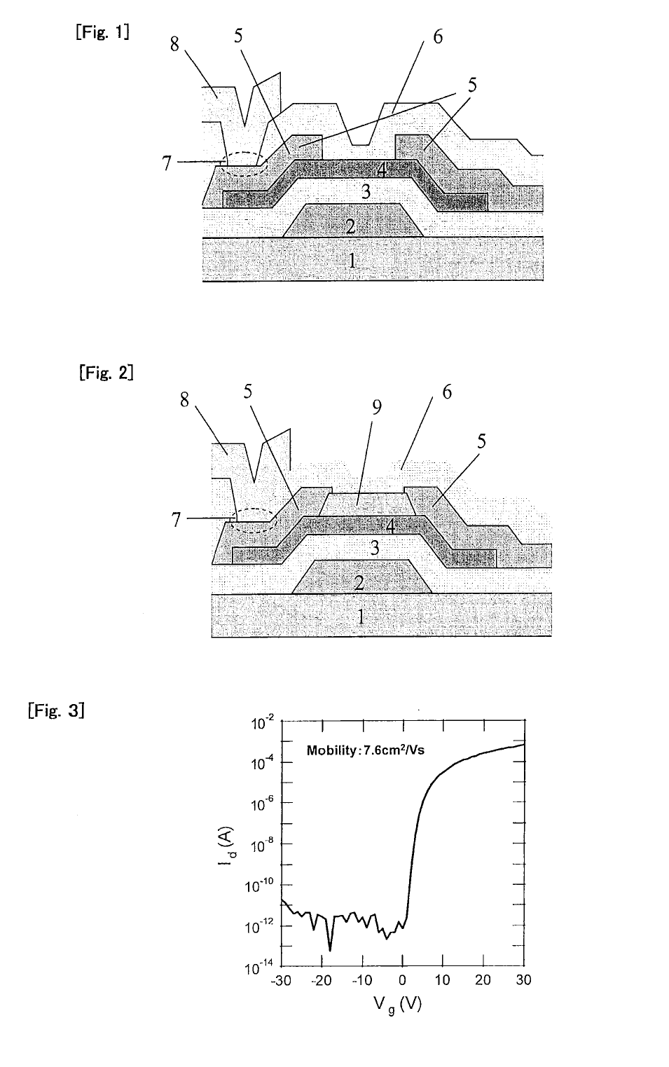

The following will explain, by reference to FIG. 1 and further to FIG. 2, embodiments of a method for producing a TFT as described above. FIG. 2 is the same as FIG. 1, except that an etch stopper layer 9 was added to the TFT shown in FIG. 1. The TFTs in Examples described below have the same structure as in FIG. 1. FIGS. 1 and 2, and the following production method, indicate one example of the preferred embodiments of the present invention, and they are not intended to limit the present invention. For example, FIG. 1 shows a TFT having a bottom gate type structure; however, the present invention is not limited thereto, and the TFTs of the present invention may be top gate type TFTs each having a gate insulator layer and a gate electrode successively on an oxide semiconductor layer.

As shown in FIG. 1, a gate electrode 2 and a gate insulator layer 3 are formed on a substrate 1, and an oxide semiconductor layer 4 is formed thereon. A source-drain electrode 5 is formed on the oxide semiconductor layer 4, and a passivation layer (or insulator layer) 6 is formed thereon, and a transparent conductive film 8 is electrically connected to the drain electrode 5 through a contact hole 7.

The method of forming the gate electrode 2 and the gate insulator layer 3 on the substrate 1 is not particularly limited, and any of the methods usually used can be employed. The kinds of the gate electrode 2 and the gate insulator layer 3 are not particularly limited, and there can be used those which have widely been used. For example, metals having low electric resistance, such as Al and Cu, high-melting-point metals having high heat resistance, such as Mo, Cr and Ti, and their alloys, can preferably be used for the gate electrode 2. Typical examples of the gate insulator layer may include a silicon oxide layer, a silicon nitride layer, and a silicon oxynitride layer. In addition, there can also be used oxides such as Al₂O₃ and Y₂O₃, and those which are formed by layering them.

Then, the oxide semiconductor layer 4 is formed. The oxide semiconductor layer 4 may preferably be formed by a DC sputtering method or an RF sputtering method using a sputtering target having the same composition as that of the thin-film, as described above. Alternatively, the film formation may be carried out by a co-sputtering method.

The oxide semiconductor layer 4 is subjected to wet etching and then patterning. Just after the patterning, heat treatment (or pre-annealing) may preferably be carried out for the purpose of improving the quality of the oxide semiconductor layer 4, resulting in an increase in the on-state current and field-effect mobility of transistor characteristics and an improvement in transistor performance. The preferred conditions of pre-annealing may be, for example, a temperature of about from 250° C. to 350° C. and a time of about from 15 to 120 minutes.

After the pre-annealing, the source-drain electrode 5 is formed. The kind of the source-drain electrode is not particularly limited, and there can be used those which have widely been used. For example, similarly to the gate electrode, metals such as Al, Mo and Cu or their alloys may be used, or pure Ti may also be used as in Examples described below.

As the method of forming the source-drain electrode 5, for example, a metal thin-film can be formed by a magnetron sputtering method and then subjected to patterning by photolithography and subsequent wet etching into an electrode.

In this method, however, the oxide semiconductor layer 4 is etched to have damage during the wet etching, which causes the occurrence of defects on the surface of the oxide semiconductor layer 4, and therefore, there is possibility that transistor characteristics may be deteriorated. To avoid such a problem, there has been widely used a method in which the etch stopper layer 9 such as SiO₂ is formed on the oxide semiconductor layer 4, as shown in FIG. 2, to protect the oxide semiconductor layer 4. In FIG. 2, the etch stopper layer 9 is formed and subjected to patterning before the formation of the source-drain electrode 5, so that the etch stopper layer 9 can protect the channel surface.

As another method of forming the source-drain electrode 5, there can be mentioned, for example, a method of forming the source-drain electrode 5 by a lift-off method after the formation of a metal thin-film by a magnetron sputtering method. This method makes it possible to process the electrode without wet etching. This method was used in Examples described below, and a metal thin-film was formed and then subjected to patterning by a lift-off method.

Then, the passivation layer (insulator layer) 6 is formed on the oxide semiconductor layer 4 by a CVD (chemical vapor deposition) method. The surface of the oxide semiconductor layer may easily become conductive due to plasma-induced damage by CVD (this seems to be because oxygen defects formed on the surface of the oxide semiconductor become electron donors), and to avoid the problem described above, N₂O plasma irradiation was carried out before the formation of the passivation layer in Examples described below. The conditions of N₂O plasma irradiation were as described in the following document.

J. Park et al., Appl. Phys. Lett., 1993, 053505 (2008)

Then, according to a conventional method, the transparent conductive film 8 is electrically connected to the drain electrode 5 through the contact hole 7. The kinds of the transparent conductive film and drain electrode are not particularly limited, and there can be used those which have usually be used. For the drain electrode, there can be used, for example, materials exemplified for the source-drain electrode described above.

### EXAMPLES

The present invention will hereinafter be described more specifically by way of Examples, but the present invention is not limited to the following Examples. The present invention can be put into practice after appropriate modifications or variations within a range meeting the gist described above and below, all of which are included in the technical scope of the present invention.

### Example 1

Based on the method described above, thin-film transistors (TFTs) as shown in FIG. 1 were produced, and the respective characteristics were evaluated.

First, a Mo thin-film of 100 nm in thickness as a gate electrode and a gate insulator layer of SiO₂ (200 nm) were successively formed on a glass substrate (“EAGLE 2000” available from Corning Incorporated, having a diameter 100 mm and a thickness of 0.7 mm). The gate electrode was formed by a DC sputtering method using a pure Mo sputtering target. The sputtering conditions were set as follows: room temperature; film formation power, 3.8 W/cm²; gas pressure, 2 mTorr, and Ar gas flow rate, 20 sccm. The gate insulator layer was formed by a plasma CVD method under the conditions: carrier gas, a mixed gas of SiH₄ and N₂O; film formation power, 1.27 W/cm³; and film formation temperature, 320° C. The gas pressure during the film formation was set to 133 Pa.

Then, oxide thin-films of various compositions as shown in Table 1 below were formed by a sputtering method using sputtering targets (described below). As the oxide thin-films, a film of In—Zn—X—O containing the X group element in In—Zn—O (inventive example) was formed, and for comparison, a film of IGZO containing Ga (conventional example), a film of In—Zn—Sn—O containing Sn (conventional example), and a film of In—Zn—Hf—O containing Hf (comparative example) were also formed. The apparatus used in the sputtering was “CS-200” available from ULVAC, Inc., and the sputtering conditions were as follows:

Substrate temperature: room temperature

Gas pressure: 5 mTorr

Oxygen partial pressure: O₂/(Ar+O₂)=2%

Film formation power: 2.55 W/cm²

Film thickness: 50 nm

In forming the film of IGZO (conventional example), a sputtering target having an In:Ga:Zn ratio (atomic % ratio) of 1:1:1 was used, and this film was formed by a DC sputtering method. In forming the oxide thin-films, i.e., the film of In—Zn—X—O (X=Al, Si, Ta, Ti, La, Mg or Nb), the film of In—Zn—Hf—O and the film of In—Zn—Sn—O, these films were formed by a co-sputtering method, in which three sputtering targets of different compositions were simultaneously discharged. More specifically, three targets, i.e., indium oxide (In₂O₃), zinc oxide (ZnO) and the oxide of the X group element, were used as the sputtering targets.

The respective contents of metal elements in the oxide semiconductor layer thus obtained were analyzed by an XPS (X-ray photoelectron spectroscopy) method.

After each oxide thin-film was formed as described above, patterning was carried out by photolithography and wet etching. “ITO-07N,” available from Kanto Chemical Co., Inc., was used as a wet etchant. In this Example, it was confirmed that no residue was observed by wet etching and etching was properly achieved in all of the oxide thin-films subjected to experiments.

After patterning of each oxide semiconductor film, pre-annealing treatment was carried out to improve the film quality. The pre-annealing was carried out at 350° C. under air atmosphere for 1 hour.

Then, a source-drain electrode was formed by a lift-off method using pure Ti. More specifically, after patterning was carried out using a photoresist, a Ti thin-film was formed by a DC sputtering method (the film thickness was 100 nm). The conditions for forming the Ti thin-film as the source-drain electrode were the same as those used in the case of the gate electrode described above. Then, an unnecessary photoresist was removed with an ultrasonic washing apparatus in acetone. For each TFT, the channel length was set to 10 μm and the channel width was set to 200 μm.

After the source-drain electrode was formed as described above, a passivation layer was formed for the protection of an oxide semiconductor layer. A layered film (having the total thickness of 150 nm) consisting of SiO₂ (having a thickness of 200 nm) and SiN (having a thickness of 150 nm) was used as the passivation layer. The formation of SiO₂ and SiN described above was carried out by a plasma CVD method using “PD-220NL” available from SAMCO Inc. In this Example, after plasma treatment was carried out by N₂O gas, the SiO₂ film and the SiN film were successively formed. A mixed gas of N₂O and SiH₄ was used for the formation of the SiO₂ film, and a mixed gas of SiH₄, N₂ and NH₃ was used for the formation of the SiN film. In both cases, the film formation power was set to 100 W and the film formation temperature was set to 150° C.

Then, a contact hole to be used for probing to evaluate transistor characteristics was formed in the passivation layer by photolithography and dry etching. Then, an ITO film (having a thickness of 80 nm) was formed by a DC sputtering method under the conditions: carrier gas, a mixed gas of argon gas and oxygen gas; film formation power, 200 W; and gas pressure, 5 mTorr. Thus, TFTs such as shown in FIG. 1 were produced.

For each of the TFTs thus obtained, (1) transistor characteristics (drain current-gate voltage characteristics, Id-Vg characteristics), (2) threshold voltage, (3) S value, (4) field-effect mobility, and (5) stress reliability after positive bias stress tests, were carried out as described below.

(1) Measurement of Transistor Characteristics

The transistor characteristics were measured using a semiconductor parameter analyzer, “4156C” available from Agilent Technology. The detailed measurement conditions were as follows:

Source voltage: 0 V

Drain voltage: 10 V

Gate voltage: from −30 to 30 V (measurement interval: 0.25 V)

Substrate temperature: room temperature

(2) Threshold Voltage (Vth)

The threshold voltage is roughly a value of the gate voltage when the transistor is sifted from the off state (the state where the drain current is low) to the on state (the state where the drain current is high). In this Example, the voltage when the drain current is around 1 nA between the on-state current and the off-state current was defined as the threshold voltage.

(3) S Value

The S value was defined as the minimum value of the gate voltage necessary for increasing the drain current by one digit in the rising edge from the off state to on state in the Id-Vg characteristics, and lower S values indicate that the TFT show a drastic increase in drain current and has more favorable device characteristics.

(4) Field-Effect Mobility μ_{FE}

The field-effect mobility μ_{FE} was derived in the saturation region where Vd>V_{g}−Vₜₕ from the TFT characteristics. In the saturation region, the filed-effect mobility μ_{FE} is derived by the expression described below, in which V_{g} and Vₜₕ are the gate voltage and the threshold voltage, respectively; I_{d} is the drain current; L and W are the channel length and channel width of a TFT element, respectively; Cᵢ is the capacitance of the gate insulator layer; and μ_{FE} is the field-effect mobility. In this Example, the field-effect mobility μ_{FE} was derived from the drain current-gate voltage characteristics (I_{d}-V_{g} characteristics) around gate voltages falling in the saturation region.

$${μ}_{FE} = \frac{\partial {I}_{d}}{\partial {V}_{g}} ( \frac{L}{{C}_{i} W ( {V}_{g} - {V}_{th} )} ) \qquad [ Mathematical Expression 1 ]$$

(5) Evaluation of Stress Reliability (Positive Bias was Applied as Stress)

In this Example, stress tests were carried out while applying positive bias to the gate electrode for simulation of environments (stress) at the time of actual panel drive. The stress tests conditions were as described below. Particularly in the case of organic EL displays, the threshold voltage is shifted by positive bias stress to lower the current value, and therefore, the threshold voltage is better to show as a small variation as possible.

Source voltage: 0V

Drain voltage: 0.1 V

Gate voltage: 20 V

Substrate temperature: 60° C.

Stress tests time: 3 hour

These results are shown in FIGS. 3 to 9 and Table 1.

TABLE 1

| | | S value | Vth | μ_{FE} | ΔVth |
|---|---|---|---|---|---|
| No. | Composition | (V/dec) | (V) | (cm²/Vs) | (V) |
| No. 1 | IGZO | 0.4 | 2 | 7.6 | 11.7 |
| | (In:Ga:Zn = 1:1:1) | | | | |
| No. 2 | In—Zn—Sn—O | 0.3 | 1 | 17.8 | 12.5 |
| | (In:Zn:Sn = 30:60:10) | | | | |
| No. 3 | In—Zn—Si—O | 0.4 | 0 | 10.1 | 5.0 |
| No. 4 | In—Zn—Al—O | 0.4 | 0 | 16.1 | 3.8 |
| No. 5 | In—Zn—Ta—O | 0.5 | −2 | 11.4 | 5.5 |
| No. 6 | In—Zn—Ti—O | 0.4 | 0 | 10.6 | 2.3 |
| No. 7 | In—Zn—Hf—O | 0.5 | 1 | 12.2 | 15.0 |
| No. 8 | In—Zn—La—O | 0.7 | −2 | 11.4 | 1.8 |
| No. 9 | In—Zn—Mg—O | 0.5 | −1 | 11.0 | 1.8 |
| No. 10 | In—Zn—Nb—O | 0.5 | −2 | 12.5 | 2.8 |

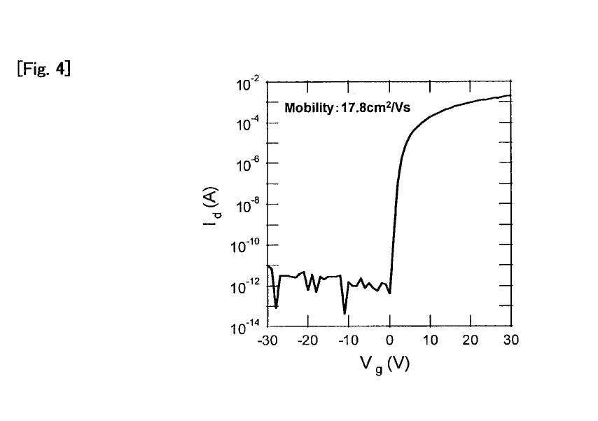

Reference is first made to FIGS. 3 to 5 and Table 1. More specifically, FIG. 3 shows the Id-Vg characteristics of the TFT using IGZO (In—Ga—Zn—O) as a conventional example for the semiconductor layer, in which IGZO has a composition of In:Ga:Zn=1:1:1 in the atomic number ratio (molar ratio). FIG. 4 shows the Id-Vg characteristics of the TFT using In—Zn—Sn—O for the semiconductor layer, in which In—Zn—Sn—O has a composition of In:Zn:Sn=30:60:10 in the atomic number ratio (molar ratio) (where the In:Zn molar ratio is 1:2). FIGS. 5A(a) to (d) show the Id-Vg characteristics of the TFTs using In—Ga—X—O for the semiconductor layer, in which Si, Al, Ta or Ti was added as the X group element, respectively. FIG. 5A(e) shows the Id-Vg characteristics in the TFT using In—Ga—Hf—O for the semiconductor layer, in which Hf was added as an element other than the X group element. In all of FIGS. 5A(a) to (e), the In amount is 30 atomic %. In FIG. 5A(a), the Si amount is 3.1 atomic %. In FIG. 5A(b), the Al amount is 1.6 atomic %. In FIG. 5A(c), the Ta amount is 1.4 atomic %. In FIG. 5A(d), the Ti amount is 2.4 atomic %. In FIG. 5A(e), the Hf amount is 3.0 atomic %. The In:Zn molar ratio is about 30:60 to 70 in all of FIGS. 5A(a) to (e). FIGS. 5B(a) to (c) show the Id-Vg characteristics of the TFTs using In—Ga—X—O for the semiconductor layer, in which La, Mg or Nb was added as the X group element, respectively. In all of FIGS. 5B(a) to (c), the In amount is 30 atomic %. In FIG. 5B(a), the La amount is 2 atomic %. In FIG. 5B(b), the Mg amount is 2 atomic %. In FIG. 5B(c), the Nb amount is 1 atomic %. The In:Zn molar ratio is about 30:60 to 70 in all of FIGS. 5B(a) to (c).

Table 1 summarizes the characteristic results of TFTs using the respective oxides described above for the semiconductor layer.

Referring to FIG. 3, first given is an explanation for the I_{d}-V_{g} characteristics of IGZO (No. 1 in Table 1) as a conventional example. As shown in FIG. 3, an increase from the negative side to the positive side in the gate voltage V_{g} causes a drastic increase in the drain current I_{d} at around V_{g}=0 V. In such a manner, the TFT shifts from the off-state at a low drain current to the on-state at a high drain current, thereby showing switching characteristics. As shown in Table 1, various characteristics of IGZO were as follows; threshold voltage Vₜₕ=2 V; S value=0.4 V/dec; on-state current (the drain current at V_{g}=30V) Iₒₙ=650 μA; and field-effect mobility μ_{FE}=7.6 cm²/Vs.

As shown in FIG. 4 and Table 1, various characteristics of In—Zn—Sn—O containing Sn not defined in the present invention (No. 2 in Table 1) were as follows: threshold voltage Vₜₕ=1 V; S value=0.3 V/dec; on-state current (the drain current at V_{g}=30V) Iₒₙ=2.04 mA; and field-effect mobility μ_{FE}=17.8 cm²/Vs. Favorable characteristics were exhibited in both examples, and in particular, In—Zn—Sn—O of No. 2, not containing Ga, had higher mobility than that of IGZO.

On the other hand, Nos. 3 to 6 and 8 to 10 in Table 1, each containing an element (the X group element=Si, Al, Ta, Ti, La, Mg or Nb) defined as the X group element in the present invention, as well as No. 7 in Table 1 containing an element (Hf) not defined in the present invention, exhibited favorable switching characteristics as shown in FIGS. 5A(a) to (e) and FIGS. 5B(a) to (c), and various characteristics shown in Table 1 were also favorable. Particularly for the field-effect mobility μ_{FE}, all examples had extremely high mobility beyond the value (7.6 cm²/Vs) of IGZO as a conventional example.

FIGS. 6 and 7 are graphs showing the results of examination on the influence that the ratio of the X group element (the X amount) and the In amount have on the field-effect mobility μ_{FE} for the TFTs of In—Zn—X—O and In—Zn—Hf—O.

FIG. 6 shows the relationship between the X amount of In—Zn—X—O (the In amount=30 atomic %) and the field-effect mobility for the X group element=Al, Si, Ta, Ti, Hf, La, Mg and Nb. In FIG. 6, filled squares are corresponding to the case where the X group element=Al; filled circles, the case where the X group element=Si; open triangles, the case where the X group element=Ta; open squares, the case where the X group element=Ti; filled triangles=Hf; open circles=Mg; open rhombuses=La; and filled rhombuses=Nb. As shown in FIG. 6, larger X amounts cause a larger lowering of the field-effect mobility, regardless of the kind of the X group element. This relationship was also seen when the In amount is in the preferred range (from 15 to 70 atomic %) of the present invention. More specifically, making the X amount equal to or smaller than approximately 5 atomic % is found to be effective in satisfying at least 50% of the field-effect mobility of No. 1 (IGZO) in Table 1 (at least 3.8 cm²/Vs), although it is different depending on the kind of the X group element. A similar tendency was also seen when Hf was used as an element other than the X group element.

FIG. 7 shows the relationship between the In amount of In—Zn—Al—O (the Al amount=1.6 atomic %) and the field-effect mobility (see open circles in FIG. 7). In FIG. 7, the relationship between the In amount and the threshold voltage Vₜₕ is shown by filled circles for reference. As shown in FIG. 7, the threshold voltage Vth hardly varies with an increase of the In amount, but the field-effect mobility μ_{FE} has a high dependency on the In amount and larger In amounts cause an improvement of the field-effect mobility. More specifically, there was seen a tendency that the field-effect mobility drastically increases at the In amount of around 10 atomic % and an increase of the mobility becomes moderate at the In amount of around 20 atomic %.

FIG. 7 shows the results obtained when Al was added as the X group element. An approximately similar tendency to that of FIG. 7 was seen when any X group element other than Al was added.

Reference is then made to FIGS. 8 and 9, in which the results are shown for the positive bias stress tests. The oxides used in FIGS. 8 and 9 had the same compositions as those shown in Table 1.

Reference is first made to FIGS. 8A and 8B. These figures show time-dependent variations of the TFT characteristics when positive bias was applied at the substrate temperature of 60° C. for from 0 to 3 hours (10800 seconds) to In—Zn—X—O (the X group element=Si, Al, Ta, Ti, La, Mg or Nb), In—Zn—Hf—O and In—Zn—Sn—O. For reference, these figures show the results obtained when the substrate temperature was 25° C. (room temperature) by dotted lines (depicted as “as depo” in FIG. 8), which are the same as the results in FIGS. 4 to 5 having the corresponding X group element.

In FIG. 8A, reference is first made to graphs of Hf and Sn not defined in the present invention. In these graphs, a comparison between the results obtained when the substrate temperature was 25° C. (dotted lines) and the results obtained when the substrate temperature was 60° C. (just after the stress tests) finds that the threshold voltage Vth is shifted in the positive direction by an increase of the substrate temperature and therefore the threshold voltage is further shifted on the positive side with an increase of the positive bias stress tests time (see “→” in the figure; along the direction of the arrow, the stress tests time becomes longer from 0 sec. to 10800 sec.). This is assumed to be because the continued application of positive bias to the TFTs results in the formation of accepter-like defects on the boundary between the gate insulator layer and the semiconductor layer, thereby causing a trapping of electrons on the boundary.

In contrast to this, when any of Al, Si, Ta, Ti, La, Mg and Nb defined in the present invention was used as the X group element, a significant variation of the threshold voltage Vₜₕ was not seen by heating at the substrate temperature of from 25° C. to 60° C., and even when positive bias stress was continuously applied, a variation of Vₜₕ was smaller than that of the case where Sn or Hf was used.

The results after the relationship between the positive bias stress tests time (sec.) and the threshold voltage variation ΔVₜₕ during the positive bias tests was classified for each kind of the X group element, based on the results of FIG. 8, are shown in FIGS. 9A and 9B (FIG. 9B is a partially enlarged view of FIG. 9A). In these figures, the threshold voltage variation ΔVₜₕ of each stress tests time was calculated as a difference between the threshold voltage at the stress time and the threshold voltage before the stress tests. These figures further show the results of IGZO (conventional example) for reference.

As seen from FIGS. 9A and 9B, the threshold voltage Vₜₕ was shifted in the positive direction with an application of positive bias, regardless of the kind of the X group element. This is assumed to be because the application of positive bias causes an increase of electrons being trapped on the boundary between the semiconductor layer and the gate insulator layer.

A comparison of the threshold voltage variation ΔVₜₕ in the respective examples reveals that it was 11.7 V for IGZO as a conventional example and ΔVₜₕ became much larger to be 16.8 V in the example containing Sn not defined in the present invention (open squares). Similarly, Δₜₕ of the example containing Hf not defined in the present invention was also larger to be 16.3 V (filled triangles). In short, these examples were found to have extremely poor positive bias stress resistance.

In contrast to this, significantly smaller ΔVₜₕ than those of these examples were found in the examples containing Al (filled squares), Si (filled circles), Ta (open triangles), Ti (open squares), La (open rhombuses), Mg (filled rhombuses) or Nb (open circles) as the X group element defined in the present invention. This is assumed to be because the addition of the above X group element defined in the present invention reduces the trapping of electrons on the boundary between the semiconductor layer and the gate insulator layer, thereby stabilizing the interstitial bonding on the boundary.

It was confirmed that the examples, in which the above X group element defined in the present invention was added, had the S value and mobility after the positive bias stress tests hardly different from those before the stress tests, thereby showing favorable characteristics.

### Example 2

In this Example, the relationship between the density of each oxide semiconductor layer and the TFT characteristics was examined for the oxides having the compositions shown in Table 2. More specifically, the density of each oxide film (having a thickness of 100 nm) was measured by the method described below, and TFTs were produced and measured for field-effect mobility in the same manner as in Example 1 described above. In Table 2, the oxides of Nos. 1 and 2 in Table 2 have the same composition (In—Zn—Sn—O) as that of as that of No. 2 in Table 1 described above; the oxides of Nos. 3 and 4 in Table 2 have the same composition (In—Zn—Al—O) as that of No. 4 in Table 1; the oxides of Nos. 5 and 6 in Table 2 have the same composition (In—Zn—Ti—O) as that of No. 6 in Table 1; the oxide of No. 7 in Table 2 has the same composition (In—Zn—La—O) as that of No. 8 in Table 1; the oxide of No. 8 in Table 2 has the same composition (In—Zn—Mg—O) as that of No. 9 in Table 1; and the oxide of No. 9 in Table 2 has the same composition (In—Zn—Nb—O) as that of No. 10 in Table 1.

(Measurement of Density of Oxide)

The density of each oxide was measured by XRR (X-ray reflectivity method). The detailed measurement conditions were as described below.

Analysis apparatus: Horizontal type X-ray diffraction apparatus Smart Lab available from Rigaku Co., Ltd.

Target: Cu (source: Kα ray)

Target output power: 45 kV, 200 mA

Preparation of Measurement Samples

Each sample was prepared by forming a film (having a thickness of 100 nm) of each oxide having each composition on a glass substrate under the sputtering conditions described below, and then carrying out the same heat treatment as the pre-annealing treatment in the TFT production process of Example 1 described above.

Sputtering gas pressure: 1 mTorr or 5 mTorr

Oxygen partial pressure: O₂/(Ar+O₂)=2%

Film formation power density: 2.55 W/cm²

Heat treatment: 350° C. under an air atmosphere for 1 hour

These results are shown together in Table 2. Nos. 2, 4 and 6 (each gas pressure during the film formation=5 mTorr) in Table 2 correspond to the same samples as those of Nos. 2, 4 and 6 in Table 1 described above, respectively, and therefore, each sample has the same filed-effect mobility.

TABLE 2

| | | Gas pressure during | | |
|---|---|---|---|---|
| | | film formation | Density | μ_{FE} |
| No. | Composition | (mTorr) | (g/cm³) | (cm²/Vs) |
| No. 1 | In—Zn—Sn—O | 1 | 6.27 | 26.5 |
| | (In:Zn:Sn = 30:60:10) | | | |
| No. 2 | In—Zn—Sn—O | 5 | 6.04 | 17.8 |
| | (In:Zn:Sn = 30:60:10) | | | |
| No. 3 | In—Zn—Al—O | 1 | 6.23 | 21.1 |
| No. 4 | In—Zn—Al—O | 5 | 6.01 | 16.1 |
| No. 5 | In—Zn—Ti—O | 1 | 6.25 | 14.2 |
| No. 6 | In—Zn—Ti—O | 5 | 6.03 | 10.6 |
| No. 7 | In—Zn—La—O | 1 | 6.21 | 15.6 |
| No. 8 | In—Zn—Mg—O | 1 | 6.23 | 13.0 |
| No. 9 | In—Zn—Nb—O | 1 | 6.22 | 13.3 |

It was found from Table 2 that when the gas pressure during the sputtering film formation is lowered from 5 mTorr (Example 1) to 1 mTorr, the film density was increased regardless of the oxide composition in all cases, along which the filed-effect mobility was highly increased. This means that defects in the film are reduced by an increase in the density of an oxide film to improve mobility and electric conductivity, resulting in an improvement in the stability of TFTs.

Table 2 shows the results of the cases where Al and Ti were used as the X group element. The same relationship between the density of the oxide film and the filed-effect mobility as described above was found even in the cases where other elements were used as the X group element. From these results, it is understood that TFTs having high mobility on a fully practicable level can be obtained, so long as the oxide semiconductor layer has a density of 6.0 g/cm³ or higher.

### EXPLANATION OF REFERENCE NUMERALS

1 Substrate
2 Gate electrode
3 Gate insulator layer
4 Oxide semiconductor layer
5 Source-drain electrode
6 Passivation layer (insulator layer)
7 Contact hole
8 Transparent conductive film
9 Etch stopper layer

1. An oxide comprising:
In;
Zn; and
at least one X group element selected from the group consisting of Al, Si, Ta, Ti, La, Mg and Nb.

2. The oxide according to claim 1, wherein an amount of X in formula: 100×[X]/([In]+[Zn]+[X]) is from 0.1 to 5 atomic %, where
wherein [In] is a content in atomic % of the In,
[Zn] is a content in atomic % of the Zn, and
[X] is a content in atomic % of the X group element.

3. The oxide according to claim 1, wherein an amount of In in formula: 100×[In]/([In]+[Zn]+[X]) is 15 atomic % or larger,
wherein [In] is a content in atomic % of the In,
[Zn] is a content in atomic % of the Zn, and
[X] is a content in atomic % of the X group element.

4. The oxide according to claim 2, wherein an amount of In in formula: 100×[In]/([In]+[Zn]+[X]) is 15 atomic % or larger.

5. The oxide according to claim 1, wherein the X group element is Al, Ti or Mg.

6. A thin-film transistor comprising an oxide according to claim 1 as a semiconductor layer of the thin-film transistor.

7. The thin-film transistor according to claim 6, wherein the semiconductor layer has a density of 6.0 g/cm³ or higher.

8. A display device comprising a thin-film transistor according to claim 6.

9. An organic EL display device comprising a thin-film transistor according to claim 6.

10. A sputtering target comprising the oxide according to claim 1.

11. The sputtering target according to claim 10, wherein an amount of X in formula: 100×[X]/([In]+[Zn]+[X]) is from 0.1 to 5 atomic %,
wherein [In] is a content in atomic % of the In,
[Zn] is a content in atomic % of the Zn, and
[X] is a content in atomic % of the X group element.

12. The sputtering target according to claim 10, wherein an amount of In in formula: 100×[In]/([In]+[Zn]+[X]) is 15 atomic % or larger,
wherein [In] is a content in atomic % of the In,
[Zn] is a content in atomic % of the Zn, and
[X] is a content in atomic % of the X group element.

13. The sputtering target according to claim 10, wherein the X group element is Al, Ti or Mg.

14. The oxide according to claim 1, wherein the X group element is Al or Ti.

15. The oxide according to claim 1, wherein the X group element is Ti.

16. The oxide according to claim 2, wherein an amount of X is from 0.5 to 3 atomic %.

17. The oxide according to claim 3, wherein an amount of In is from 15 to 70 atomic %.

18. The oxide according to claim 3, wherein an amount of In is from 20 to 50 atomic %.

19. The thin-film transistor according to claim 6, wherein the semiconductor layer has a density of 6.2 g/cm³ or higher.

20. The thin-film transistor according to claim 6, wherein the semiconductor layer has a density of 6.4 g/cm³ or higher.
